(19) United States
(12) Patent Application Publication
(10) Pub. No.: US 2014/0264695 A1
(43) Pub. Date: Sep. 18, 2014

(54) Image Sensor and Method of Manufacturing the Same

(71) Applicants: Yun-Ki Lee, Seoul (KR); Chang-Rok Moon, Seoul (KR); Duck-Hyung Lee, Seongnam-si (KR)

(72) Inventors: Yun-Ki Lee, Seoul (KR); Chang-Rok Moon, Seoul (KR); Duck-Hyung Lee, Seongnam-si (KR)

(21) Appl. No.: 14/212,045

(22) Filed: Mar. 14, 2014

(30) Foreign Application Priority Data
Mar. 14, 2013 (KR) 10-2013-0027314

(51) Int. Cl. H01L 27/146

(52) U.S. Cl. CPC H01L 27/1462; H01L 27/14685; H01L 27/14621; H01L 27/14627; H01L 27/1464
USPC 257/432; 438/58

(57) ABSTRACT

An image sensor includes a semiconductor layer having a first surface and a second surface opposite to each other and including a photodiode and a hydrogen containing region adjacent the first surface. A crystalline anti-reflective layer is on the first surface of the semiconductor layer, and is configured to allow hydrogen atoms to penetrate into the first surface of the semiconductor layer. Driving transistors and wires are on the second surface of the semiconductor layer, and a color filter and a micro lens are on the anti-reflective layer. The hydrogen containing region contains hydrogen atoms that combine with defects at the first surface.

### CROSS-REFERENCE TO RELATED APPLICATION

This application claims priority under 35 USC §119 to Korean Patent Application No. 10-2013-0027314, filed on Mar. 14, 2013 in the Korean Intellectual Property Office (KIPO), the disclosure of which is herein incorporated by reference in its entirety.

### FIELD

Example embodiments relate to image sensors and methods of manufacturing the same. More particularly, example embodiments relate to backside illumination image sensors and methods of manufacturing the same.

### BACKGROUND

In order to increase an amount of a light incident on a photodiode, backside illumination image sensors that include a backside surface for receiving light therethrough have been developed. However, in backside illumination image sensors, problems such as a dark current and/or white spots may occur.

SUMMARY

Example embodiments provide an image sensor having good characteristics.

Example embodiments provide a method of manufacturing an image sensor having good characteristics.

According to example embodiments, an image sensor includes a semiconductor layer having a first surface and a second surface opposite to each other and including a photodiode and a hydrogen containing region in the first surface, a crystalline anti-reflective layer on the first surface of the semiconductor layer to allow hydrogen atoms to penetrate into the first surface of the semiconductor layer, driving transistors and wires on the second surface of the semiconductor layer, and a color filter and a micro lens on the anti-reflective layer. The hydrogen containing region contains hydrogen atoms combined defects at the first surface.

In example embodiments, the anti-reflective layer may include metal oxide.

In example embodiments, the anti-reflective layer may include at least one selected from the group consisting of aluminum oxide, hafnium oxide, lanthanum oxide, lanthanum aluminum oxide, lanthanum hafnium oxide, hafnium aluminum oxide, titanium oxide, tantalum oxide and zirconium oxide.

In example embodiments, the anti-reflective layer may have positive, negative or neutral charge characteristics.

In example embodiments, an image sensor may further include an impurity region adjacent to the first surface of the semiconductor layer and doped with p-type impurities.

In example embodiments, an image sensor may further include a protection layer on the anti-reflective layer.

In example embodiments, the protection layer may include silicon oxide, silicon oxynitride, silicon nitride or silicon carbide.

According to example embodiments, in a method of manufacturing an image sensor, a photodiode is formed in a semiconductor layer including a first surface and a second surface opposite to the first surface. Driving transistors and wires are formed on the second surface of the semiconductor layer. A crystalline anti-reflective layer is formed on the first surface of the semiconductor layer. The anti-reflective layer is configured to allow hydrogens to penetrate into the first surface of the semiconductor layer. Hydrogen ions are provided to the first surface of the semiconductor layer to form a hydrogen containing region which includes hydrogen atoms combined with defects at the first surface. A color filter and a micro lens are formed on the crystalline anti-reflective layer.

In example embodiments, the anti-reflective layer may be crystallized by a deposition process.

In example embodiments, the anti-reflective layer may be formed by a chemical vapor deposition (CVD) process, a physical vapor deposition (PVD) process or an atomic layer deposition (ALD) process.

In example embodiments, the hydrogen ion implantation may include a plasma process.

In example embodiments, the hydrogen ion implantation may be performed within a temperature range of about 0 to about 400 degrees Celsius to form the hydrogen containing region.

In example embodiments, after the hydrogen ion implantation, at least one of a thermal process, a thin film deposition process and ultra-violet surface treatment process may be further performed.

In example embodiments, an impurity region may be further formed adjacent to the first surface of the semiconductor layer and doped with p-type impurities.

In example embodiments, a protection layer may be further formed on the crystalline anti-reflective layer.

According to an image sensor in accordance with example embodiments, the defects of a light receiving surface of the semiconductor layer are reduced to limit the dark current. The image sensor in accordance with example embodiments has excellent characteristics. The image sensor may be manufactured by simple processes.

### BRIEF DESCRIPTION OF THE DRAWINGS

Example embodiments will be more clearly understood from the following detailed description taken in conjunction with the accompanying drawings. FIGS. 1 to 12 represent non-limiting, example embodiments as described herein.

FIG. 1 is a circuit diagram illustrating a unit pixel included in a CMOS image sensor.

FIG. 2 is a cross-sectional view illustrating a back illumination image sensor in accordance with example embodiments. FIGS. 3A and 3B are enlarged views illustrating portions of the back illumination image sensor in FIG. 2.

FIGS. 4A to 4F are cross-sectional views illustrating a method of manufacturing the backside illumination image sensor in FIG. 2.

FIG. 5 is a cross-sectional view illustrating a backside illumination image sensor in accordance with example embodiments.

FIG. 6 is a cross-sectional view illustrating a method of manufacturing the backside illumination image sensor in FIG. 5.

FIG. 7 is a cross-sectional view illustrating a backside illumination image sensor in accordance with example embodiments.

FIG. 8 is a cross-sectional view illustrating a method of manufacturing the backside illumination image sensor in FIG. 7.

FIG. 9 is a cross-sectional view illustrating a backside illumination image sensor in accordance with example embodiments.

FIG. 10 is a cross-sectional view illustrating a method of manufacturing the backside illumination image sensor in FIG. 9.

FIG. 11 is a graph representing dark current characteristics of Comparative sample 1 and Comparative sample 2.

FIG. 12 is a graph representing white spots characteristics of Comparative sample 1 and Comparative sample 2.

### DETAILED DESCRIPTION

Example embodiments will now be described more fully with reference to the accompanying drawings, in which example embodiments are shown. Example embodiments may, however, be embodied in many different forms and should not be construed as limited to the example embodiments set forth herein. In the drawings, the thicknesses of layers and regions are exaggerated for clarity. Like reference numerals in the drawings denote like elements, and thus their description will be omitted.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms first, second, third, etc. may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

FIG. 1 is a circuit diagram illustrating a unit pixel included in a CMOS image sensor.

The unit pixel may be provided in an active pixel region.

Referring to FIG. 1, the unit pixel may include a photodiode (PD) 62 for sensing light, a transmission transistor 52 that transfers photon clusters detected by the photodiode to a floating diffusion region (FD), a reset transistor 54 that resets the floating diffusion region, a driving transistor 56 that generates an electric signal in response to the transferred photon cluster at the floating diffusion region, and a selection transistor 58 that transfers the electric signal outside the pixel.

The transmission transistor 52, the reset transistor 54 and the selection transistor 58 may be controlled by a transmission control signal TX, a reset control signal RX and a selection control signal, respectively. According to the direction of incoming light, image sensors may be classified as one of a typical CMOS image sensor and a backside illumination CMOS image sensor.

In a typical CMOS image sensor, light incident on each pixel may be blocked by wires, thereby decreasing the efficiency of light collection. However, in a backside illumination image sensor, the wires may not be provided in the active pixel region, i.e., a light incident surface, such that the light may be received through the entire region of the active pixel, thereby increasing the efficiency of light collection.

### Embodiment 1

FIG. 2 is a cross-sectional view illustrating a back illumination image sensor in accordance with example embodiments. FIGS. 3A and 3B are enlarged views illustrating portions of the back illumination image sensor in FIG. 2.

FIG. 3A represents a portion of the back illumination image sensor using a material having positive or neutral charge characteristics as an anti-reflective layer. FIG. 3B represents a portion of the back illumination image sensor using a material having a negative charge characteristics as anti-reflective layer.

Referring to FIG. 2, the back illumination image sensor may include a semiconductor layer 100a including a first surface 101a and a second surface 101b opposite to the first surface 101a. The semiconductor layer 100a may include a photodiode (PD) 104 and a hydrogen containing region 116. An anti-reflective layer 114 may be provided on the first surface 101a of the semiconductor layer 100a. Driving transistors 106 and wires 110 may be provided on the second surface 101b of the semiconductor layer 100a. A color filter 120 and a micro lens 122 may be provided on the anti-reflective layer 114.

The semiconductor layer 100a may include a planarized semiconductor substrate. The semiconductor layer 100a may include a layer formed by a selective epitaxial growth (SEG) process. The semiconductor layer 100a may have a thickness of about several micrometers to several tens micrometers.

The first surface 101a of the semiconductor layer 100a may be a backside surface that receives light incident thereon. The second surface 101b of the semiconductor layer 100a may be a frontside surface. The semiconductor layer 100a may include a plurality of photodiodes 104 adjacent to the first surface. Each of the photodiodes may serve as a pixel element. The photodiodes 104 may be isolated from each other by isolation layers 102, respectively.

The anti-reflective layer 114 may include a material layer capable of allowing hydrogen atoms to penetrate through the layer and into the first surface 101a of the semiconductor layer 100. For example, the anti-reflective layer 114 may include a crystalline layer. When a crystalline layer is used as the anti-reflective layer 114, hydrogen atoms may easily penetrate into each photodiode through the anti-reflective layer 114 and the first surface of each photodiode. When a non-crystalline layer is used as the anti-reflective layer 114, hydrogen atoms may not easily penetrate into the photodiodes. Therefore, it may be preferable to use a crystalline layer as the anti-reflective layer.

The anti-reflective layer 114 may include a material layer having a high light transmittance. The anti-reflective layer 114 may reduce/prevent reflection of incident light. The charge characteristics of the anti-reflective layer 114 may not be limited. That is, the anti-reflective layer 114 may have positive, negative or neutral charge characteristics.

However, in some embodiments, it may be preferable that the anti-reflective layer 114 have negative charge characteristics to reduce/prevent dark current from being generated at the first surface 101a of the semiconductor layer 100a. As illustrated in FIG. 3B, when the anti-reflective layer 114 has negative charge characteristics, a hole accumulation region 130 may be generated at the semiconductor layer 100a adjacent to the anti-reflective layer 114 due to the negative characteristics of the anti-reflective layer 114. Positively charged carriers (i.e., holes) may accumulate in the hole accumulation region 130. Electrons generated at a defective region of the first surface 101a of the semiconductor layer 100a may be neutralized by the holes in the hole accumulation region 130, which may reduce/prevent the dark current from flowing into the photodiode 104.

As illustrated in FIG. 3A, when the anti-reflective layer 114 has positive or neutral characteristics, a hole accumulation region 130 may be not formed.

The anti-reflective layer 114 may include a material, such as a crystalline metal oxide. A crystalline metal oxide material may have the negative charge characteristics. For example, the anti-reflective layer 114 may include aluminum oxide, hafnium oxide, lanthanum oxide, lanthanum aluminum oxide, lanthanum hafnium oxide, hafnium aluminum oxide, titanium oxide, tantalum oxide and/or zirconium oxide.

The anti-reflective layer 114 may have a thickness equal to or less than 1500 angstroms. When the anti-reflective layer 114 has a thickness more than 1500 angstroms, the hydrogens may not easily penetrate into the underlying photodiodes. Further, the transmittance of light incident on the photodiodes may be decreased.

The defective region of the first surface 101a of the semiconductor layer 100a may be combined with hydrogen atoms included in the hydrogen containing region 116. Defects in the defective region of the first surface 101a may include, for example, dangling bonds, lattice mismatches, etc. A dangling bond or a silicon vacancy may be combined with the hydrogen atoms included in the hydrogen containing region 116 to form a silicon-hydrogen combination. The defects in the defective region thereof may be cured by the silicon-hydrogen combination. Each of hydrogen atoms combined with the defects may be monatomic.

Depending on the number of defects, the hydrogen content included in the hydrogen containing region 116 may vary. When the number of the defects in the first surface of the semiconductor layer 100a is high, the number of the hydrogen atoms included in the hydrogen containing region 116 may be high also.

By providing the hydrogen containing region 116, the defects of the first surface 101a of the semiconductor layer 100a may be repaired, which may reduce dark current caused by the electrons generated at the defects.

In a typical image sensor, defects at a surface of the semiconductor layer 100a may remain un-repaired. In an image sensor in accordance with example embodiments, defects at the first surface of the semiconductor layer 100a may be reduced/cured to reduce the dark current. Furthermore, reducing defects at the surface of the semiconductor layer may also reduce the occurrence of white spots in the resulting image.

Referring again to FIG. 2, a color filter 120 and a micro lens 122 may be disposed on each photodiode 104. Light from outside may be incident on the photodiodes 104 through the color filter 120 and the micro lens 122.

Wires and transistors may not be provided between the color filter 120 and the first surface 101a of the semiconductor layer 100a. This may also reduce the distance that light travels from the micro lens 122 to the photodiode 104, and may also reduce scattered reflection and/or blocking of the light, which may thereby increase light transmittance and/or light sensitivity of the sensor.

Transistors 106 included in the unit pixel, such as a transmission transistor, a reset transistor or a selection transistor, may be provided on the second surface 101b, i.e., the front side surface, of the semiconductor layer 100a. Transistors included in a peripheral circuit may also be formed on the front side surface of the semiconductor layer 100a.

An insulating interlayer 108 may be provided on the second surface 101b of the semiconductor layer 100a to cover the transistors. Wires 110 may be provided in the insulating interlayer 108 at various metallization layers therein. The wires 110 may include a metal or a metal alloy having a low resistance.

An image sensor in accordance with example embodiments may not include an impurity region doped with p-type impurities at the first surface 101a of the semiconductor layer 100a. Accordingly, the occurrence of white spots due to defects associated with p-type impurities may be reduced. Further, defects at the first surface of the semiconductor layer may be reduced to reduce/prevent dark current. Therefore, an image sensor in accordance with example embodiments may have excellent characteristics.

FIGS. 4A to 4F are cross-sectional views illustrating methods of forming the backside illumination image sensor shown in FIG. 2.

Referring to FIG. 4A, a semiconductor substrate 100 including a semiconductor material may be provided. The semiconductor substrate 100 may include a bulk semiconductor substrate or a silicon-on-insulator (SOI) substrate. Although it is not illustrated, a selective epitaxial growth (SEG) process may be performed on the semiconductor substrate 100 to form a semiconductor epitaxial layer thereon. The semiconductor substrate 100 may include a first surface, i.e., a backside surface, and a second surface, i.e., a frontside surface.

An isolation layer 102 may be formed at the second surface of the semiconductor substrate 100 to define an active region and an isolation region in the semiconductor substrate 100. For example, a shallow trench isolation (STI) process may be performed to form a plurality of trenches at the semiconductor substrate 100. The trenches may be filled up with insulating material to form the isolation layers 102.

The second surface of the semiconductor substrate 100 of the active region may be doped with impurities to form a plurality of photodiodes (PDs) 104. An ion implantation process may be performed several times using a plurality of ion implantation masks to form the photodiodes 104.

A gate insulation layer and a gate conductive layer may be formed on the second surface of the semiconductor substrate 100. The gate insulation layer and the gate conductive layer may be patterned to form a plurality of gate electrodes. Impurity regions may be formed at both end portions of each gate electrode to form transistors 106. The transistors 106 may include a transmission transistor, a reset transistor and a selection transistor. Also, the transistors 106 may include transistor in a peripheral circuit.

In this embodiment, the transistors 106 may be formed after the photodiodes 104 are formed. However, the order of forming the transistors and the PDs may not be limited thereto. By performing the processes, all the transistors required in the image sensor may be provided.

Referring to FIG. 4B, an insulating layer 108 may be formed over the transistors 106. Wires 110 may be formed in the insulating layer 108.

The wires 110 may be multi-layered wires. The wires 110 may include a metal or a metal alloy having a low resistance. A photolithography process may be performed to form the wires 100. Alternatively, a damascene process may be performed to form the wires 100.

The number and the structure of layers of the wires 110 may not be limited thereto and may vary in accordance with a circuit design.

Referring to FIG. 4C, a supporting substrate 112 may be adhered on a top surface of the insulating interlayer 108 to support the semiconductor substrate 100. The first surface of the semiconductor substrate 100 may be ground to reduce a thickness of the semiconductor substrate 100. The grinding process may be performed on the semiconductor substrate 100 to form a semiconductor layer 100a having a thickness of a several micrometers.

The driving transistor 106 and the wires 110 may be provided on a second surface 101b of the semiconductor layer 100a. The photodiodes may be provided adjacent to a first surface 101a of the semiconductor layer 100a. Defects, such as dangling bonds and/or lattice defects, may be generated at the first surface 101a of the semiconductor layer 100a.

Subsequent processes may be performed on the first surface 101a of the semiconductor layers 100a. Accordingly, hereinafter, in FIGS. 4D to 4F, the structure is inverted such that the first surface 101a of the semiconductor layer 100a is located in upper portion of the figures.

Referring to FIG. 4D, an anti-reflective layer 114 may be formed on the first surface 101a of the semiconductor layer 100a.

The anti-reflective layer 114 may be a crystalline layer. When a crystalline layer is used as the anti-reflective layer 114, hydrogen may easily penetrate into each PD through the anti-reflective layer 114 and the first surface 101a of each PD. The anti-reflective layer 114 may be a material layer having a high light transmittance.

The anti-reflective layer 114 may be formed by a chemical vapor deposition (CVD) process, a physical vapor deposition (PVD) process, an atomic layer deposition (ALD) process, etc.

The anti-reflective layer 114 may be formed as a crystalline layer during the deposition process. That is, an additional process may not be required to transform a non-crystalline layer to a crystalline layer. Therefore, the photodiodes 104, the driving transistors 106 and the wires 110 may not be deteriorated by the crystallization process.

A process for forming the anti-reflective layer 114 may be performed at a temperature equal to or less than about 400 degrees Celsius. For example, the process for forming the anti-reflective layer 114 may be performed within a temperature range of about 50 to about 400 degrees Celsius. If the process for forming the anti-reflective layer 114 is performed at a temperature more than 400 degrees Celsius, the circuit elements may be deteriorated. If the process for forming the anti-reflective layer 114 is performed at a temperature less than 50 degrees Celsius, a crystalline layer may not easily formed.

The anti-reflective layer 114 may include a material, such as a crystalline metal oxide. For example, the crystalline metal oxide may have negative charge characteristics. The anti-reflective layer 114 may include aluminum oxide, hafnium oxide, lanthanum oxide, lanthanum aluminum oxide, lanthanum hafnium oxide, hafnium aluminum oxide, titanium oxide, tantalum oxide and/or zirconium oxide.

The charge characteristics of the anti-reflective layer 114 may not be limited. That is, the anti-reflective layer 114 may have positive, negative or neutral charge characteristics. However, in some embodiments, it may be desirable for the anti-reflective layer 114 to have negative charge characteristics to limit dark current generated at the first surface 101a of the semiconductor layer 100a. When the anti-reflective layer 114 has negative charge characteristics, a hole accumulation region 130 in FIG. 3 may be generated at the semiconductor layer 100a adjacent to the anti-reflective layer 114 by the negative characteristics of the anti-reflective layer 114.

The anti-reflective layer 114 may have a thickness equal to or less than 1500 angstroms.

Referring to FIG. 4E, the first surface 101a of the semiconductor layer 100a on which the anti-reflective layer 114 is formed may be doped with reactive ions, including hydrogen ions, to form a hydrogen containing region 116 at the first surface 101a of the semiconductor layer 110a. The hydrogen containing region 116 may be formed after the anti-reflective layer 114 is formed. Accordingly, the hydrogen ions may be prevented from outgassing and hydrogen bonds may be increased.

The hydrogen containing region may be formed by process, such as a hydrogen plasma process. The hydrogen plasma process may be performed at a temperature equal to or less than 400 degrees Celsius. Also, the hydrogen plasma process may be performed at a common temperature or below the common temperature. In example embodiments, the hydrogen plasma process may be performed within a temperature range of about 0 to about 400 degrees Celsius. If the hydrogen plasma process is performed at a temperature more than 400 degrees Celsius, the circuit elements may be deteriorated. If the hydrogen plasma process is performed at a temperature less than 0 degree Celsius, plasma and hydrogen bonds may not easily be generated.

Hydrogen atoms may penetrate into the first surface 101a of the semiconductor layer 100a and may combine with defects in the semiconductor layer 100a to passivate the defects. The defects, such as dangling bonds and/or lattice mismatches, may bond with the hydrogen atoms, which may cure the defects at the first surface 101a of the semiconductor layer 100a. The hydrogen atoms may be monatomic, which may facilitate strong combinations. At least one inert gas, such as Ar, He, Kr or Ne, may be used in the hydrogen plasma process.

The source of reactive ions including the hydrogen atoms may include H2, H20 or H2O2. For example, when H2 is used to provide a source of reactive ions, the monatomic hydrogen atoms may easily be formed at the hydrogen plasma process. The oxygen included in the H₂0 may be combined with an oxygen vacancy of the metal oxide as the anti-reflective layer 114. The defects of the first surface 101a of the semiconductor layer 100a may be combined with the hydrogen atoms to repair the defects.

After the hydrogen containing region 116 is formed, a thermal process, a thin film deposition process and/or an ultra-violet surface treatment may be further performed. The subsequent processes may be performed to increase the hydrogen bonds.

Referring to FIG. 4F, a color filter 120 and a micro lens 122 may be formed on the anti-reflective layer 114.

As mentioned above, an image sensor in accordance with example embodiments may not include an impurity region doped with p-type impurities at the first surface 101a of the semiconductor layer. Accordingly, defects due to the p-type impurities may be reduced. Also, the defects of the first surface 101a of the semiconductor layer may be reduced to limit the dark current. The image sensor in accordance with example embodiments may have excellent characteristics.

### Embodiment 2

FIG. 5 is a cross-sectional view illustrating a backside illumination image sensor in accordance with further example embodiments.

The backside illumination image sensor is substantially the same as or similar to that of FIG. 2 except for an additional protection layer on the anti-reflective layer.

Referring to FIG. 5, the back illumination image sensor may include a semiconductor layer 100a including a first surface 101a and a second surface 101b opposite to the first surface 101a. The semiconductor layer 100a may include a photodiode (PD) 104 and a hydrogen containing region 116 adjacent to the first surface 101a. An anti-reflective layer 114 may be provided on the first surface 101a of the semiconductor layer 100a. Driving transistors 106 and wires 110 may be provided on the second surface 101b of the semiconductor layer 100a. The semiconductor layer 100a, the PD 104, the anti-reflective layer 114, the hydrogen containing region 116, the driving transistors 106 and the wires 110 may be substantially similar to those shown in FIG. 2.

A protection layer 118 may be provided on the anti-reflective layer 114. The protection layer 118 may reduce/prevent moisture absorption. The protection layer 118 may include silicon oxide, silicon oxynitride, silicon nitride, silicon carbide, etc.

The material composition and/or thickness of the protection layer 118 may be adjusted in accordance with stress of the anti-reflective layer 114 beneath the protection layer 118, permittivity, charge characteristics, leakage current characteristics, etc. As the protection layer 118 is provided, it may increase reliability of the image sensor.

A color filter 120 and a micro lens 122 may be provided on the protection layer 118.

As defects on the first surface of the semiconductor layer 100a are cured by hydrogen atoms in the hydroden containing region 116, dark current may be reduced. Therefore the image sensor in accordance with example embodiments may have excellent characteristics. Further, the image sensor may have high reliability due to the protection layer.

FIG. 6 is a cross-sectional view illustrating a method of manufacturing the backside illumination image sensor in FIG. 5.

First, processes substantially similar to those illustrated with reference to FIGS. 4A to 4E may be performed to provide the structure in FIG. 4E.

Referring to FIG. 6, a protection layer 118 may be formed on an anti-reflective layer 114.

A chemical vapor deposition (CVD) process, a physical vapor deposition (PVD) process or an atomic layer deposition (ALD) process may be performed to form the protection layer 118. A process for forming the protection layer 118 may be performed at a temperature equal to or less than about 400 degrees Celsius. For example, the process for forming the protection layer 118 may be performed within a temperature range of about 50 to about 400 degrees Celsius. If the process for forming the protection layer 118 is performed at a temperature more than 400 degrees Celsius, circuit elements may be adversely affected. If the process for forming the protection layer 118 is performed at a temperature less than 50 degrees Celsius, it may be difficult to form the protection layer 118.

As illustrated in FIG. 5, a color filter 120 and a micro lens 122 may be sequentially formed on the protection layer 118. As defects on the first surface of the semiconductor layer 100a are cured by hydrogen atoms in the hydroden containing region 116, dark current may be reduced. Therefore the image sensor in accordance with example embodiments may have excellent characteristics. Further, the image sensor may have high reliability due to the protection layer.

### Embodiment 3

FIG. 7 is a cross-sectional view illustrating a backside illumination image sensor in accordance with still further example embodiments.

The backside illumination image sensor may be substantially similar to the backside illumination image sensor of FIG. 2 except that an additional impurity region is provided.

Referring to FIG. 7, the back illumination image sensor may include a semiconductor layer 100a including a first surface 101a and a second surface 101b opposite to the first surface 101a. The semiconductor layer 100a may include a photodiode (PD) 104 and a hydrogen containing region 116. An anti-reflective layer 114 may be provided on the first surface 101a of the semiconductor layer 100a. Driving transistors 106 and wires 110 may be provided on the second surface 101b of the semiconductor layer 100a. A color filter 120 and a micro lens 122 may be provided on the anti-reflective layer 114. Each of the members may be substantially similar to those of FIG. 2,

An impurity region 124 doped with p-type impurities may be provided beneath the anti-reflective layer 114. The p-type impurities may include boron. The impurity region 124 may be formed beneath the first surface of the semiconductor layer 100a. The impurity region 124 may have a low impurity concentration. The p-type impurities of the impurity region 124 may provide holes which recombine electrons which are generated at defective portions of the first surface of the semiconductor layer 100a,

However, as the defective portions thereof may be almost cured by silicon-hydrogen bonds, the electrons which are generated at the defective portions thereof may be very little. Accordingly, the p-type impurities of the impurity region 124 may have an auxiliary role to decrease a dark current.

The hydrogen containing region 116 and the impurity region 124 may not be separated. As illustrated in FIG. 7, the hydrogen containing region 116 may include the impurity region 124. Alternatively, although it is not illustrated, the impurity region 124 may include the hydrogen containing region 116.

In an image sensor in accordance with some example embodiments, defects at the first surface of the semiconductor layer 100a may be at least partially cured to reduce dark current. An auxiliary impurity region may also be provided to at least partially reduce the dark current. The image sensor may have excellent characteristics.

FIG. 8 is a cross-sectional view illustrating a method of manufacturing the backside illumination image sensor in FIG. 7.

First, processes substantially similar to those illustrated with reference to FIGS. 4A to 4C may be performed to provide the structure in FIG. 4C.

Referring to FIG. 8, a portion adjacent to the first surface of the semiconductor layer 100a may be doped with p-type impurities to form an impurity region 124. The p-type impurities may include boron. In the ion implantation process, the impurity region 124 may have a low impurity concentration to reduce defects of the first surface of the semiconductor layer 100a.

Processes substantially similar to those illustrated with reference to FIGS. 4D to 4F may then be performed. As illustrated in FIG. 7, the backside illumination image sensor includes the impurity region 124.

In an image sensor in accordance with some example embodiments, defects in the first surface of the semiconductor layer 100a may be cured to reduce dark current. In the ion implantation process, the defects of the first surface of the semiconductor layer 100a may be reduced. The image sensor may have excellent characteristics.

### Embodiment 4

FIG. 9 is a cross-sectional view illustrating a backside illumination image sensor in accordance with further example embodiments.

The backside illumination image sensor may be substantially similar to the backside illumination image sensor of FIG. 7 except that an additional protection layer may be provided.

Referring to FIG. 9, the back illumination image sensor may include a semiconductor layer 100a including a first surface 101a and a second surface 101b opposite to the first surface 101a, a photodiode (PD) 104, a hydrogen containing region 116, an anti-reflective layer 114, driving transistors 106, wires 110, an impurity region 124, a color filter 120 and a micro lens 120 substantially the same as those of FIG. 7, respectively.

As illustrated in FIG. 9, the protection layer 118 may be provided on the anti-reflective layer 114. That is, the protection layer 118 may be interposed between the anti-reflective layer 114 and the color filter 120.

The protection layer 118 may include silicon oxide, silicon oxynitride, silicon nitride, silicon carbide, etc.

In the image sensor in accordance with some embodiments, defects at the first surface of the semiconductor layer 100a may be cured to reduce the dark current. As the protection layer 118 is provided, it may increase reliability of the image sensor.

FIG. 10 is a cross-sectional view illustrating a method of manufacturing the backside illumination image sensor in FIG. 9.

First, processes substantially the same as those illustrated with reference to FIGS. 4A to 4C may be performed to provide the structure in FIG. 4C.

As illustrated with reference to FIG. 8, a portion adjacent to the first surface of the semiconductor layer 100a may be doped with p-type impurities to form an impurity region 124.

Processes substantially similar to those illustrated with reference to FIGS. 4D to 4E to form an anti-reflective layer 114 and a hydrogen containing region 116 may then be performed.

Referring to FIG. 10, a protection layer 118 may be formed on the anti-reflective layer 114,

A chemical vapor deposition (CVD) process, a physical vapor deposition (PVD) process or an atomic layer deposition (ALD) process may be performed to form the protection layer 118. A process for forming the protection layer 118 may be performed within a temperature range of about 50 to about 400 degrees Celsius.

As illustrated in FIG. 9, a color filter 120 and a micro lens 122 may sequentially be formed on the protection layer 118.

In an image sensor in accordance with some example embodiments, defects at the first surface of the semiconductor layer 100a may be cured to reduce the dark current. The image sensor may have excellent characteristics.

Experiments for Samples

Sample 1

A backside illumination image sensor in accordance with the embodiment 1 was provided. An anti-reflective layer of the backside illumination image sensor was formed using a crystalline hafnium oxide. A hydrogen containing region was provided beneath the anti-reflective layer.

Comparative Sample 1

A backside illumination image sensor for comparison with Sample 1 was provided. An anti-reflective layer of the backside illumination image sensor was formed using a noncrystalline silicon nitride. An impurity region doped with p-type impurities was provided beneath the anti-reflective layer. The p-type impurities included boron.

Comparative Sample 2

A backside illumination image sensor for comparison with Sample 1 was provided. An anti-reflective layer of the backside illumination image sensor was formed using a noncrystalline hafnium oxide. An impurity region doped with p-type impurities was provided beneath the anti-reflective layer. The p-type impurities included boron.

Comparison of Dark Current Characteristics

Dark currents of Sample 1, Comparative sample 1 and Comparative sample 2 were measured. When the value of the dark current of Comparative sample 1 was set to 100, the normalized values of the dark currents of Comparative sample 2 and Sample 1 were measured.

FIG. 11 represents dark current characteristics of Comparative sample 1 and Comparative sample 2.

In the FIG. 11, the values on Y axis are normalized values where the value of the dark current of Comparative sample 1 is set to 100 (arbitrary units).

Referring to FIG. 11, the value of dark current of Sample 1 is about 25, that is, one fourth of the value of Comparative sample 1. Thus, the backside illumination image sensor of Sample 1 exhibits a reduction of dark current in comparison with the comparative sample 1 of 75%.

The value of Comparative sample 2 is about 50. The backside illumination image sensor of Sample 1 exhibits a reduction of dark current in comparison with that of Comparative sample 2 of 50%.

Accordingly, the backside illumination image sensor in accordance with example embodiments may reduce the dark current.

Comparison of White Spots

Numbers of the white spots of Sample 1, Comparative sample 1 and Comparative sample 2 were measured. When the number of the white spots of Comparative sample 1 was set to 100, the normalized values of the white spots of Comparative sample 2 and Sample 1 were measured.

FIG. 12 represents white spots characteristics of Comparative sample 1 and Comparative sample 2.

In the FIG. 12, the values on Y axis are normalized values when the number of the white spot of Comparative sample 1 is set to 100 (arbitrary units).

Referring to FIG. 12, the values of Sample 1 is about 15, that is, fifteen hundredths of the value of Comparative sample 1. The backside illumination image sensor of Sample 1 reduces the white spots by 85% in comparison with Comparative sample.

The value of Comparative sample 2 is about 50. The backside illumination image sensor of Sample 1 reduces the white spots by 70% in comparison with Comparative sample 2.

Accordingly, the backside illumination image sensor in accordance with example embodiments may reduce the white spots.

While example embodiments have been particularly shown and described, it will be understood by one of ordinary skill in the art that variations in form and detail may be made therein without departing from the spirit and scope of the claims.

What is claimed is:

1. An image sensor, comprising:
a semiconductor layer having a first surface and a second surface opposite the first surface and including a photodiode and a hydrogen containing region adjacent the first surface, the hydrogen containing region containing hydrogen atoms that combine with defects at the first surface;
a crystalline anti-reflective layer on the first surface of the semiconductor layer, wherein the crystalline anti-reflective layer is configured to allow hydrogen atoms to penetrate through the crystalline anti-reflective layer and into the first surface of the semiconductor layer;
driving transistors and wires on the second surface of the semiconductor layer; and
a color filter and a micro lens on the anti-reflective layer.

2. The image sensor of claim 1, wherein the anti-reflective layer comprises a metal oxide.

3. The image sensor of claim 2, wherein the anti-reflective layer comprises at least one of aluminum oxide, hafnium oxide, lanthanum oxide, lanthanum aluminum oxide, lanthanum hafnium oxide, hafnium aluminum oxide, titanium oxide, tantalum oxide and/or zirconium oxide.

4. The image sensor of claim 1, wherein the anti-reflective layer has negative charge characteristics.

5. The image sensor of claim 1, further comprising an impurity region in the semiconductor layer adjacent to the first surface of the semiconductor layer, wherein the impurity region is doped with p-type impurities.

6. The image sensor of claim 1, further comprising a protection layer on the anti-reflective layer.

7. The image sensor of claim 6, wherein the protection layer comprises silicon oxide, silicon oxynitride, silicon nitride or silicon carbide.

8. A method of manufacturing an image sensor, the method comprising:
forming a photodiode in a semiconductor layer, the semiconductor layer including a first surface and a second surface opposite to the first surface;
forming driving transistors and wires on the second surface of the semiconductor layer;
forming a crystalline anti-reflective layer on the first surface of the semiconductor layer, the crystalline anti-reflective layer configured to allow hydrogen atoms to penetrate through the crystalline anti-reflective layer and into the first surface of the semiconductor layer;
forming a hydrogen containing region in the semiconductor layer adjacent the first surface of the semiconductor layer, the hydrogen containing region including hydrogen atoms combined with defects at the first surface of the semiconductor layer;
forming a color filter and a micro lens on the crystalline anti-reflective layer.

9. The method of claim 8, wherein the anti-reflective layer is crystalline.

10. The method of claim 8, wherein the anti-reflective layer is formed by a chemical vapor deposition (CVD) process, a physical vapor deposition (PVD) process or an atomic layer deposition (ALD) process.

11. The method of claim 8, wherein forming the hydrogen containing region comprises performing a plasma process.

12. The method of claim 8, wherein the hydrogen ion implantation is performed within a temperature range of about 0 degrees Celsius to about 400 degrees Celsius to form the hydrogen containing region.

13. The method of claim 8, further comprising, after forming the hydrogen containing region, performing at least one of a thermal process, a thin film deposition process and ultra-violet surface treatment process.

14. The method of claim 8, further comprising forming an impurity region adjacent to the first surface of the semiconductor layer and doped with p-type impurities.

15. The method of claim 8, further comprising forming a protection layer on the crystalline anti-reflective layer.

16. An image sensor, comprising:
a semiconductor layer having a first surface and a second surface opposite the first surface
a photodiode in the semiconductor layer;
a hydrogen containing region between the photodiode and the first surface, the hydrogen containing region containing hydrogen atoms that passivate crystalline defects at the first surface;
a crystalline anti-reflective layer on the first surface of the semiconductor layer;
an impurity region in the semiconductor layer adjacent to the first surface of the semiconductor layer, wherein the impurity region is doped with p-type impurities;
a protection layer on the anti-reflective layer; wherein the protection layer comprises silicon oxide, silicon oxynitride, silicon nitride or silicon carbide;
driving transistors and wires on the second surface of the semiconductor layer; and
a color filter and a micro lens on the anti-reflective layer.
